(19) United States
(12) Patent Application Publication
(10) Pub. No.: US 2026/0135544 A1
(43) Pub. Date: May 14, 2026

(54) IMON RECONSTRUCTION VIA KALMAN FILTER IN DIGITAL QUAD CONTROLLER

(71) Applicant: MaxLinear, Inc., Carlsbad, CA (US)

(72) Inventors: Glenn Chance Dunlap, III, Houston, TX (US); Rajat Channappanavar, Bengaluru (IN)

(73) Assignee: MaxLinear, Inc., Carlsbad, CA (US)

(21) Appl. No.: 19/383,439

(22) Filed: Nov. 7, 2025

Related U.S. Application Data
(60) Provisional application No. 63/718,538, filed on Nov. 8, 2024.

(51) Int. Cl. H03K 3/017; H03H 17/02

(52) U.S. Cl. CPC H03K 3/017; H03H 17/0257

(57) ABSTRACT

A system for switching power supply is disclosed herein. The system may include a controller and a plurality of switching power supplies. The controller may include a processing device. The processing device may determine a monitored current of at least one switching power supply of the plurality of switching power supply, and determine, based on the monitored current, an induction prediction. The processing device may determine, a voltage input prediction corresponding to the at least one switching power supply, and output, by the controller, the voltage input prediction to the at least one switching power supply.

### RELATED APPLICATION

This application claims the benefit of U.S. Provisional Application No. 63/718,538, filed Nov. 8, 2024, the disclosure of which is incorporated herein by reference in its entirety for all purposes.

The examples discussed in the present disclosure are related to current reconstruction via Kalman filters in digital quad controllers.

### BACKGROUND

Unless otherwise indicated herein, the materials described herein are not prior art to the claims in the present application and are not admitted to be prior art by inclusion in this section.

The field of power electronics has seen considerable advancements with the advent of digital control in power supply units. Digital controllers have increasingly replaced analog counterparts due to their flexibility, precision, and adaptability to various operating conditions and system conditions. Digital power supply control involves managing the conversion and regulation of electrical power using sophisticated algorithms and digital processing techniques.

Digital control in switching power supplies has evolved to allow for management of single phase and multiple phases in power conversion processes. Such multiphase digital controllers synchronize several power stages to efficiently handle high-current demands while reducing thermal stress and electromagnetic interference. This synchronization enables the power supply to deliver a stable and low-ripple output voltage, which is critical for the reliable operation of sensitive electronic devices and systems. However, many digital switching regulators and controllers lack real-time control with minimal latency, precise phase alignment, and current balancing across the multiple phases.

The subject matter claimed in the present disclosure is not limited to examples that solve any disadvantages or that operate only in environments such as those described above. Rather, this background is only provided to illustrate one example technology area where some examples described in the present disclosure may be practiced.

### SUMMARY

Accordingly, some examples may include a system for a switching power supply. The system may include a controller and switching power supplies. The controller may include a processing device. The processing device may determine a monitored current of at least one switching power supply of the switching power supply and determine, based on the monitored current, an inductor current prediction. The system may determine a voltage input state corresponding to the at least one switching power supply. The system, by the controller, may output the voltage input state to the at least one switching power supply.

A system for controlling a multiphase switching power supply may include a control loop to manage switching power supplies, and a hysteresis window generator to dynamically adjust switching thresholds for the switching power supplies.

A method may include determining a monitored current of at least one switching power supply of switching power supplies; determining, based on the monitored current, an induction prediction; determining, a voltage input prediction corresponding to the at least one switching power supply based on the induction prediction; and outputting the voltage input prediction to the at least one switching power supply.

The objects and advantages of the examples will be realized and achieved at least by the elements, features, and combinations particularly pointed out in the claims.

Both the foregoing general description and the following detailed description are given as examples and are explanatory and are not restrictive of the invention, as claimed.

### BRIEF DESCRIPTION OF THE DRAWINGS

So that the manner in which the above recited features of the present disclosure can be understood in detail, a more particular description of the disclosure, briefly summarized above, may be had by reference to examples, some of which are illustrated in the appended drawings. It is noted, however, that the appended drawings illustrate only some aspects of this disclosure and the disclosure may admit to other equally effective examples.

To facilitate understanding, identical reference numerals have been used, where possible, to designate identical elements that are common to the figures. It is contemplated that elements and features of one example may be beneficially incorporated in other examples without further recitation.

FIG. 1 illustrates a schematic of an exemplary switching power supply system, in accordance with some examples;

FIG. 2 illustrates schematic of an exemplary control loop circuit for use in the system shown in FIG. 1, in accordance with some examples;

FIG. 3 illustrates a schematic of a current monitor for IMON reconstruction, in accordance with some examples;

FIGS. 4A-4E illustrate graphical representations for determining an inductor current, in accordance with some examples; and

FIGS. 5A-5C depict simulations corresponding to IMON reconstruction, in accordance with some examples.

### DETAILED DESCRIPTION

The present disclosure will now be described in detail with reference to the drawings, which are provided as illustrative examples of the disclosure so as to enable those skilled in the art to practice the disclosure. Notably, the figures and examples below are not meant to limit the scope of the present disclosure to a single example, but other examples are possible by way of interchange of some or all of the described or illustrated elements. Moreover, where certain elements of the present disclosure can be partially or fully implemented using known components, only those portions of such known components that are necessary for an understanding of the present disclosure will be described, and detailed descriptions of other portions of such known components will be omitted so as not to obscure the disclosure.

As used herein, the singular form of “a”, “an”, and “the” include plural references unless the context clearly dictates otherwise. As used herein, the statement that two or more parts or components are “coupled” shall mean that the parts are joined or operate together either directly or indirectly (i.e., through one or more intermediate parts or components, so long as a link occurs). As used herein, “directly coupled” means that two elements are directly in contact with each other. As used herein, “fixedly coupled” or “fixed” means that two components are coupled so as to move as one while maintaining a constant orientation relative to each other. As used herein, “operatively coupled” means that two elements are coupled in such a way that the two elements function together. It is to be understood that two elements “operatively coupled” does not require a direct connection or a permanent connection between them. As utilized herein, “substantially” means that any difference is negligible, or that such differences are within an operating tolerance that are known to persons of ordinary skill in the art and provide for the desired performance and outcomes as described in one or more examples herein. Descriptions of numerical ranges are endpoints inclusive.

As used herein, the word “unitary” means a component is created as a single piece or unit. That is, a component that includes pieces that are created separately and then coupled together as a unit is not a “unitary” component or body. As employed herein, the statement that two or more parts or components “engage” one another shall mean that the parts exert a force against one another either directly or through one or more intermediate parts or components. As employed herein, the term “number” shall mean one or an integer greater than one (i.e., a plurality). Directional phrases used herein, such as, for example and without limitation, top, bottom, left, right, upper, lower, front, back, and derivatives thereof, relate to the orientation of the elements shown in the drawings and are not limiting upon the claims unless expressly recited therein.

Embodiments described as being implemented in hardware should not be limited thereto, but can include examples implemented in software, or combinations of software and hardware, and vice-versa, as will be apparent to those skilled in the art, unless otherwise specified herein. In the examples described herein, an example showing a singular component should not be considered limiting; rather, the invention is intended to encompass other examples including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

The examples described herein relate generally to an advanced digital controller (hereinafter “the controller”) that may significantly enhance management in a single or multiphase power supply system. The controller may include a multiphase control loop, which may provide superior performance and efficiency in regulating and distributing electrical power.

As described in detail below, the controller may intelligently orchestrate activity across multiple power phases to ensure synchronized load sharing and minimize power loss. Such synchronization may be advantageous for reducing ripple and improving the overall stability of the power supply. The controller may facilitate precision phase alignment and current balancing, ensuring steady performance and mitigating the potential for phase drift or imbalance.

The controller may include IMON current reconstruction utilizing filtering techniques, such as a Kalman filter, for precisely emulating the inductor current waveform, enabling accurate real-time adjustments to phases. Filtering and reconstructed current monitoring may be advantageous for dynamic current management, allowing the controller to respond effectively to the demands of complex and fluctuating loads. Moreover, the application of the Kalman filter may facilitate sensor-less input voltage (Vin) sensing. The controller may use the reconstructed current data to indirectly derive the Vin, thereby enhancing the system's ability to monitor and adapt to changes in the input supply. Such sensor-less, indirect Vin sensing capability may be particularly advantageous, eliminating the use for additional hardware components, streamlining integrated circuit (IC) design, and reducing manufacturing costs.

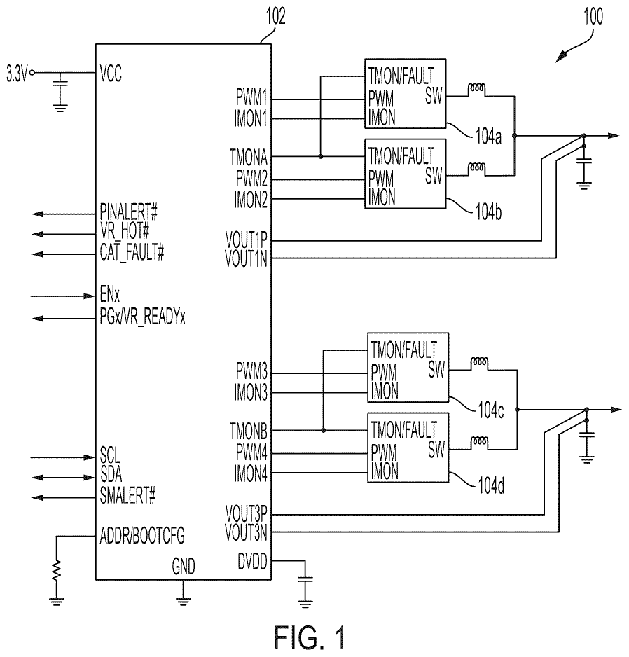

FIG. 1 illustrates a schematic of a switching power supply system 100 (hereinafter “system 100”). System 100 may include multi-phase digital quad controller 102 (hereinafter “controller 102”), and switching power stage (SPS) 104a, 104b, 104c, 104d. Controller 102 may encompass a communication architecture that advantageously maximizes efficiency and power distribution by performance with four switched power supplies (e.g., SPS 104a, 104b, 104c, 104d) within system 100. System 100, via controller 102, may be configured to efficiently manage and drive up to four outputs simultaneously via SPS 104a, 104b, 104c, 104d, (collectively “SPS 104”). Accordingly, controller 102 may perform logic operations, decision-making, and overall system management, while SPS 104 may encompass individual power conversion units, which controller 102 may manage. Such SPS 104a, 104b, 104C, 104d may be referred to as “phases” in a multiphase power supply system (e.g., system 100). One or more of the 4 SPS 104a, 104b, 104c, 104d may have different Vin voltages. System 100 may include a single phase and/or single output. For example, SPS 104 may include a single output and phase (not shown in FIG. 1).

Operational parameters may be governed via software, offering a versatile and user-friendly interface for configuration. Controller 102 software suite may include a graphical user interface (GUI), which may allow for effortless setup and fine-tuning of the device. Such GUI may empower users to adjust settings, monitor performance, and tailor the controller to specific applications without hardware modifications.

System 100 via controller 102 and SPS 104 may be configured for control and adjustability, offering unparalleled precision in power regulation. Such software-driven approach may provide the flexibility to adapt to a wide array of operational conditions, so that controller 102 may deliver optimal performance across various scenarios. With such level of control, users may expect a responsive system capable of meeting the demands of sophisticated power systems.

As shown in FIG. 1, controller 102 may include various input pins, output pins and/or input/output (I/O) pins. For example, controller 102 may include voltage common collector (VCC) pin. VCC pin may be the main power supply input to controller 102, providing the power for the internal circuits and logic of controller 102.

Enable (ENx)/power good (PGx)/voltage regulation ready (VR_READYx) pins may enable inputs for the power stages and power good outputs indicating when the phase is ready or within regulation. SV_CLK, SV_DATA, SV_ALERT #pins (not shown) may provide a serial interface for communication with the controller, for example, for software based configuration, monitoring, and/or alerting purposes. SCL/SDA/SMALERT #pins may correspond to an inter-integrated circuit (I²C) bus interface, and/or other communication protocols for ICs. For example, SCL pin may be the clock line, SDA pin may encompass the data line, and SMALERT #pin may encompass an alert signal.

Controller 102 may be configured for single resistor selection via address or boot configuration (ADDR/BOOTCFG) pin. Single resistor selection may be the use of a single resistor to set the address (i.e., ADDR) or configuration (i.e., CFG) of a device, which may be advantageous for electronic devices that communicate over a bus, such as I²C or system management bus (SMBus). Utilizing a single resistor to set the address or configuration may simplify the hardware design. For example, instead of multiple jumpers or switches, only one component may be used, which may minimize space on the printed circuit board (PCB) and reduce manufacturing complexity. Moreover, in a multi-device system where several devices of the same kind may be present on the same bus, devices may use a unique address. The single resistor selection may allow for easy hardware-based address assignment by changing the resistance value (e.g., impedance), which may be read by the device at startup and correspond to a specific address. Similarly, if the resistor (e.g., impedance) is used for configuration, changing its value may alter operational parameters of the device without reprogramming or using additional hardware.

Single resistor selection may reduce the overall component count in the system, which may lead to cost savings and enhanced reliability due to fewer potential points of failure. For example, in communication protocols like I²C, where each device on the bus may have a unique address, the single resistor may allow for easy adjustment of each device's address without changing the firmware or using dip-switches. Single resistor selection provides that the device may be configured to work with different systems or in different modes, based on external hardware settings rather than software ones, which may be useful during the manufacturing process or in field configuration.

In the context of controller 102, utilizing a single resistor for address or configuration setting may enable the device to seamlessly integrate into a variety of systems with minimal adjustments. This feature may allow for quick and easy customization of the controller's operation, which may be particularly advantageous in complex systems with multiple controllers or in situations where the controller may be swiftly adapted to different operating conditions or functionalities.

ADDR/BOOTCFG pin may be used to set the device address on the communication bus or to configure system 100 startup settings. Ground (GND)/digital voltage (DVDD) pins may ground the digital power supply pins for the controller, providing reference and power for digital logic circuits.

SPS 104a-104d may include pins and interconnections for communicating with controller 102. In some examples, such communication interfaces may include, but are not limited to, pins shown as temperature monitoring and fault detection (TMON/FAULT), pulse width modulation (PWM), current monitoring (IMON), and/or switch (SW). The TMON/FAULT pin may be purposed for temperature monitoring and fault detection, enabling proactive system protection. The PWM pin may correspond to the pulse width modulation signals used for controlling the power stages. The IMON pin may provide real-time current monitoring feedback, advantageous for the regulation of power delivery. And the SW pin may serve as a switch node, a junction in the power conversion process. Together, SPS 104 pins may form an integrated network facilitating efficient signal transmission and system regulation.

For example, PWM1, PWM2 outputs from controller 102 to SPS 104a, 104b may determine the pulse width modulation signals, controlling the timing and duration of the power transistors' switching events within SPS 104a, 104b. IMON1, IMON2 may correspond to current monitoring. IMON1, IMON2 outputs may represent the monitored current flowing through the respective SPS (e.g. SPS 104a, 104b). IMON1, IMON2 outputs may be utilized for feedback in a control loop (not shown) to regulate the current or for protection purposes.

Controller 102 may include temperature monitoring A (TMONA) pin which may be configured for temperature monitoring. As shown in FIG. 1, TMONA may be a shared terminal and used for temperature monitoring across multiple SPS 104a, 104b. TMONA may collect temperature data to ensure that system 100 operates within under or substantially under a temperature threshold corresponding to safe thermal conditions. For example, TMONA circuitry may trigger a fault condition when an over-temperature event is detected.

Controller 102 may include pins voltage output positive (VOUTIP), voltage output negative (VOUTIN). Voltage output pins may be the positive and negative terminals of the output voltage from SPS 104a, 104b. VOUTIP, VOUTIN pins may provide the regulated voltage output that system 100 provides. For example, PWM signals may be advantageous for controlling the switching power devices in SPS 104, which may convert the DC input to a regulated output with the desired voltage and current characteristics. The IMON signals (e.g., IMON1, IMON2, IMON 3, IMON4) may be advantageous for ensuring that the amount of current flowing through SPS 104a, 104b, 104c, 104d may be within the system 100 specifications and for making dynamic adjustments based on changing loads.

As shown in FIG. 1, the sharing of the TMONA signal between different phases (e.g., SPS 104a, 104b) offers an integrated temperature monitoring system that simplifies the thermal management by reducing the number of sensors used, thereby streamlining the hardware design with minimal components. The VOUTIP and VOUTIN may represent a differential pair, facilitating system 100's ability to minimize noise and ensure accurate voltage delivery, which may be advantageous in high-precision applications or in environments with significant electrical interference.

As shown by pins PWM3 and PWM4, system 100 may include a modular, symmetrical protocol in the design of controller 102 that drives four outputs (i.e., SPS 104a, 104b, 104c, 104d). Such modular, symmetrical protocol, along with the shared architecture for other phases, may facilitate a uniform and modular approach to power management. Such dual or mirrored approach in the design of system 100 components (e.g., 102, 104) may be advantageous for a variety of reasons.

For example, the symmetrical design may allow for phases, represented by PWM1/IMON1 through PWM4/IMON4, to follow the same or substantially the same architectural framework. Such modular configuration may facilitate scalability since additional phases may be added following the same architectural framework, which may simplify processes and ensures stability for SPS 104 output. Moreover, modularity may also aid in manufacturing and troubleshooting, as the same, or substantially the same, components and design considerations apply to each SPS 104.

Employing such mirrored architecture across switching power supplies may ensure that phases behaves similarly, leading to similar performance when driving multiple outputs. Similar performance may be particularly advantageous in applications where accurate load balancing across phases may be used. The mirrored configuration for the control of phases ensures that the performance characteristics, such as efficiency, response time, and thermal management, may be uniform across the board, reducing the complexity of system-level optimization. The symmetry in the design inherently provides redundancy. If one phase were to fail, the other phases, being identical, may share the increased load, enhancing the system's overall reliability. For example, in applications where downtime is not permitted, such redundant design approach may ensure steady operation, with the remaining phases compensating for the one that is out of service.

While the PWM signals may control the timing and duty cycle for power delivery in each phase, the IMON signals may provide a feedback mechanism for current monitoring. Such feedback monitoring may be advantageous for closed-loop control and protection. The mirrored design may provide that similar feedback control algorithms may be applied across all phases, streamlining the development of control firmware and software. Moreover, as shown in FIG. 1, temperature monitors TMONA, TMONB may have a shared connection to multiple phases, reflecting an integrated approach to temperature management across the controller system. The single-point monitoring may simplify the thermal management of the system, because the same cooling strategy may be applied uniformly.

The SW pins may represent the switch node in a buck converter topology, which may be points where the high-frequency switching occurs. Having a symmetrical design for the SW pins across phases provides that the parasitic elements and switching characteristics may be uniform, which may simplify the layout considerations for electromagnetic compatibility and efficiency. Such steady switch node design may mean that the ripple current and voltage may be easily managed and filtered, as the inductors and capacitors in the output filters may be identical, conserving the cost and space.

Controller 102 may uniformly manage multiple phases due to the symmetry discussed above. Uniform management may allow for a streamlined software and hardware interface, because the control algorithms may not be individually tailored for difference phases. Such uniformity may allow for a more intuitive and user-friendly GUI for device setup, because the settings for one phase may be applicable to the others. Doing so may reduce the complexity of system configuration and maintenance. Thus, the dual approach in the design of system 100 may provide a steady and efficient method for managing multiple power stages in a power supply system. The uniformity and symmetry of the phases provide that the system may be optimized for performance, ease of use, and reliability, all of which are highly advantageous in modern electronic applications.

Controller 102 and/or SPS 104a, 104b, 104c, 104d may include a number of processing units and/or CPUs that may be used in applications involving processors and/or software: One or more aspects or features of the subject matter described herein may be realized in digital electronic circuitry, integrated circuitry, specially designed application specific integrated circuits (ASICs), field programmable gate arrays (FPGAs), state machines, computer hardware, firmware, software, and/or combinations thereof. These various aspects or features may include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device. The programmable system or computing system may include clients and servers. A client and server may be generally remote from each other and typically interact through a communication network. The relationship of client and server may arise by virtue of computer programs running on the respective computers and having a client-server relationship to each other.

These computer programs, which may also be referred to programs, software, software applications, applications, components, or code, include machine instructions for a programmable processor, and may be implemented in a high-level procedural language, an object-oriented programming language, a functional programming language, a logical programming language, and/or in assembly/machine language. As used herein, the term “machine-readable medium” (or “computer readable medium”) may refer to any computer program product, apparatus and/or device, such as for example magnetic discs, optical disks, memory, and programmable logic devices (PLDs), used to provide machine instructions and/or data to a programmable processor, including a machine-readable medium that receives machine instructions as a machine-readable signal. The term “machine-readable signal” (or “computer readable signal”) may refer to any signal used to provide non-transitory machine readable instructions and/or data to a programmable processor. The machine-readable medium may store such machine instructions non-transitorily, such as for example as would a non-transient solid-state memory or a magnetic hard drive or any equivalent storage medium. The machine-readable medium may alternatively or additionally store such machine instructions in a transient manner, such as for example as would a processor cache or other random access memory associated with one or more physical processor cores.

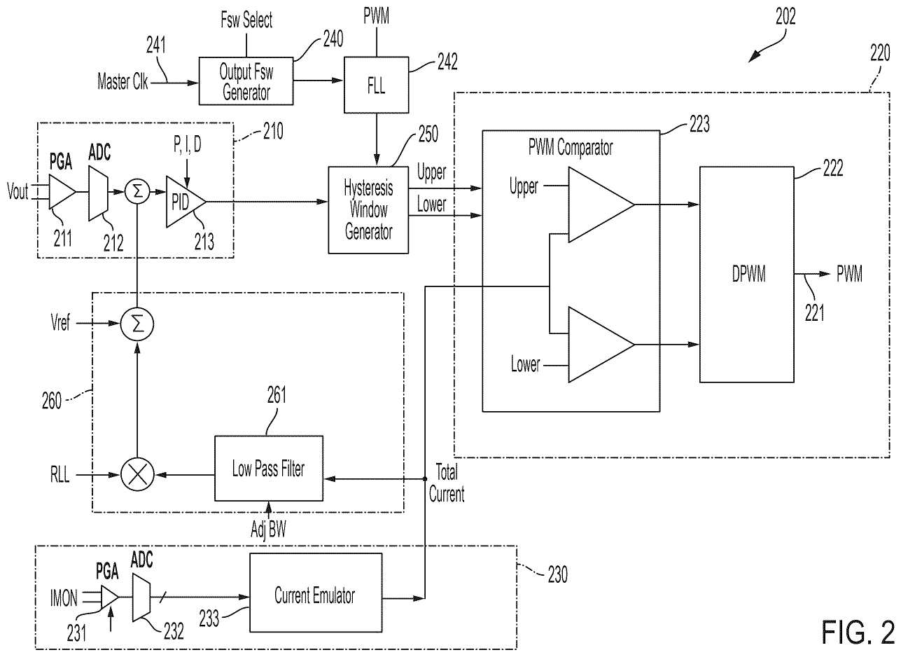

FIG. 2 depicts control loop circuitry 202 (hereinafter “control loop 202”). Control loop 202 may facilitate Vin sensing via IMON reconstruction. Control loop 202 may include voltage regulator 210, pulse width circuitry 220, and current emulator block 230. Control loop 202 may include a dual-loop for current and voltage regulation.

Control loop 202 may incorporate a master clock 241 that orchestrates output switching frequency (FSW) generator 240. Output FSW generator 240 may determine the transistors' switching frequency in the power stages, and may be directly influenced by the FSW select input, which may initiate the output FSW generation process. The generated FSW may not only drive the power transistors but may also be stabilized by the frequency locked loop (FLL) 242, which may incorporate a PWM output. For example, control loop 202 may not have constant frequency due to its hysteretic nature. Thus, to emulate a fixed frequency, FLL 242 may be utilized for comparing the desired frequency (e.g., output of output FSW generator 240) against a free running switching frequency of the power supply (e.g., PWM input) and provide a correction signal that may adjust the hysteresis window.

FLL 242 may synchronize the oscillator's frequency, which may be derived from the master clock 241 with an external reference signal, ensuring uniformity in the switching frequency throughout power switching operation. Such synchronization may be advantageous for maintaining steady performance and efficiency of the power conversion process within control loop 202. FLL output signal may be fed to hysteresis window generator (HWG) 250.

HWG 250 may create a hysteresis band for current loop 202, where the power stage may be turned on when the current drops below a lower threshold (e.g., lower) and off when the current exceeds an upper threshold (e.g., upper). Thus, HWG 250 may establish a defined hysteresis band that may control the operational thresholds for the power stages within controller 102. The hysteresis band may be selected based on the desired switching frequency. Thus, when the monitored current falls beneath the lower threshold, HWG 250 may prompt the power stage to activate, thereby increasing the current. Conversely, upon detecting that the current has surpassed the upper threshold, HWG 250 may deactivate the power stage, thus reducing the current flow.

Accordingly, such dynamic hysteresis band may serve as an advantageous regulatory mechanism, operating in tandem with FLL 242 and proportional-integral-derivative (PID) controller 213 inputs via voltage regulator (VR) 210. FLL 242 may be used to adjust hysteresis for ensuring steady frequency and provide a stabilized frequency input to ensure steady switching intervals, while the PID controller 213 may adjust the band position to control the amount of current going to the output. Such PID controller 213 input may allow for fine-tuned adjustments based on the hysteresis band's positioning, effectively providing a voltage controlled current source. Such dual input strategy employed by HWG 250 may enable precise control over the current, contributing to controller 102's overall objective of maintaining a robust, stable, and efficient power delivery system across multiple phases. The hysteresis band's implementation within control loop 202 exemplifies controller 102 design, which may be adept at handling the complexities of modern power management and distribution demands.

Control loop 202 may include a VR 210. VR 210 may include programmable gain amplifier (PGA) 211, analog-to-digital converter (ADC) 212, and PID controller 213. PGA 211 may be implemented for an initial setup procedure. VR 210, which may be configured for low latency in the feedback path, may be advantageous for real-time control systems where the response time may significantly impact the system's performance. For example, in power supplies for computing applications, quick adjustments to the output voltage may maintain stability. Such low latency in the feedback path may provide rapid response to changes in output voltage. ADC 212 may convert the analog voltage to a digital signal, which may be used for telemetry and for feedback in a control loop.

VR 210 via PID controller 213 may be configured for dynamic voltage error control. For example, the “voltage error” may be the difference between the desired voltage set point and the actual Vout. PID controller 213 may process this error to adjust the control signals sent to the power stage. The “proportional” part of PID controller 213 may respond to the voltage error, the “integral” part may respond to the accumulation of past errors, and the “derivative” part may respond to the rate of change of the error. By processing the error in these three ways, PID controller 213 may dynamically adjust the power output to quickly correct deviations from the desired voltage, ensuring tight regulation. As utilized herein dynamic voltage error control refers to system 100's ability to adapt to changing conditions on-the-fly. The PID algorithm of PID controller 213 may allow for a dynamic response by automatically adjusting the control effort based on the error and a history. Such functionality may be advantageous in power systems where load conditions may change rapidly, and the power supply may react just as quickly to prevent overshoot, undershoot, or oscillations in the output voltage.

PID controller 213 may process a feedback signal that may be conditioned by integrated filtering circuitry (e.g., summation circuit 260). Summation circuit 260 may advantageously tailor the feedback for optimal PID controller performance. Summation circuit 260 may include low pass filter (LPF) 261, which may serve to attenuate high-frequency noise and transients, ensuring stable PID operation by allowing low-frequency content pertinent to the control loop.

The feedback signal of summation circuit 260 may be derived from a current emulator block 230, which may generate a signal indicative of the actual current, albeit in a synthesized form. Current emulator block 230 may include a PGA 231, an ADC 232, and current emulator 233. Current emulator 233 may employ an emulated current to enhance the precision and responsiveness of the power management process. Such approach may circumvent the issue of switching noise contamination within control loop 202, which may degrade the quality of the current signal and lead to inefficiencies and inaccuracies in power regulation.

Such emulation, via so-called IMON reconstruction, may simulate the actual current based on various input parameters and system responses. The use of emulated current in control loop 202 may be advantageous for ensuring that the feedback used for control decisions may be devoid of the high-frequency noise typically induced by switching activities. Such excursions, when present, may compromise system 100's ability to respond to changes effectively.

Advantageously, current emulator 233 may facilitate zero-latency in current sensing, which means that system 100 may have immediate access to current information without the delay that may accompany physical current measurement processes. Current emulator 233 may provide full bandwidth current information meaning system 100 may accurately track current variations across a wide range of frequencies, ensuring robust performance even under rapidly changing loads or supply conditions.

Thus, incorporating emulated current into control loop 202 may facilitate real-time adjustments to power stage operations, optimizing performance, and minimizing the risk of overcurrent or undercurrent conditions that may harm system components or the load. By strategically bypassing the noise of the power switching process, the controller 102 may ensure that the decision-making process is based on clean, reliable data, thereby enhancing the overall stability of the power supply system.

Such forward-thinking application of IMON reconstruction may facilitate controller 102's advanced capabilities. For example, such emulated current signal may offer a facsimile of the real current flow, which PID 213 may utilize for real-time corrective actions. By utilizing such emulation approach, system 100 may maintain a high degree of control fidelity without being affected by the noise and variability of direct current measurements.

Summation circuit (2) 260 may be where the various feedback signals, including the output, may be summed with a reference voltage (Vref). Vref may serve as the target voltage level for control loop 202, and the summing circuit may combine Vref with the feedback signals to determine any error between the actual and desired output. The error signal generated from this summation may be fed into the PID controller 213, which may adjust the power stage operation to correct the error. Summation circuit 260 may include a low pass filter 261.

Control loop 202 may use predicted output current to dynamically adjust PWM signals for switching power supplies. Control loop 202 may include PWM circuitry 220. PWM circuitry 220 may include PWM comparator 223 and digital pulse width modulator (DPWM) 222. For example, the PWM signal 221 may include the output voltage response (i.e., error signal from PID 213) and the current position based on the current emulator 233. Such signal may be compared at PWM 223 and decision made when to turn on or off the PWM signal 221. Both voltage and current may be used to make a control decision in this architecture. DPWM 222 may modulate the width of the pulses to control the power delivered to the load based on the commands from both control loops. In context of the operation of the dual loop control functionality, the voltage loop may maintain the output voltage by adjusting the duty cycle of the DPWM based on the difference between the setpoint and the actual voltage. The current loop may ensure that the output current does not exceed a certain level, safeguarding the system against overcurrent conditions.

PID controller 213's inputs from summation circuit 260 may affect PWM Comparator 223, which may be responsible for modulating the PWM signals in accordance with PID 213 output. Such modulation may govern the switching behavior of the power stages within controller 102, aligning the output power delivery with system 100 real-time demands. The synergistic operation of the filtering circuitry, current emulation, PID controller, and PWM comparator underscores the comprehensive and dynamic nature of the control strategy employed by the controller 102.

Referring back to FIG. 1, by connecting phases together at the output using a single control loop, the controller 102 may synchronize the phases to distribute power more evenly. Controller 102 may operate with permitted permutations of multiphase. Such permutations may include assigning a number of individual PWM outputs to a designated output (one of the four channels) to facilitate a flexible configuration where controller 102 may manage anywhere from 1 to 4 outputs with phase counts ranging from 0 to 4, with the ability to allocate these phases across the channels. Such examples may provide for alternative configurations such as: a single 4 phase power supply, a dual output each with dual phases, or 4 independent and separate outputs. Three phases may be used for one channel, and one phase for another, which may be useful for applications where one channel uses significantly more power than the others, herein referred to as a 3+1 configuration. In a 2+2 configuration, an even distribution of power may occur across two channels, which may be beneficial for balancing load and thermal performance. Such capability also suggests that the controller 102 may dynamically adjust the phase configuration based on the load or other system conditions, which may be an advanced feature demonstrating adaptability and efficiency.

For example, hysteresis window generator 250 may be part of influencing the switching behavior of the power supply. HWG 250 may set two thresholds which may include an upper and a lower limit for a parameter (such as current or voltage). When the parameter exceeds the upper threshold, the system may react, by turning off a switch. And HWG 250 may not turn the switch back on until the parameter falls below the lower threshold.

The use of a single hysteresis window generator 250 in a controller 102 may be particularly advantageous for load sharing among the different phases and help to maintain a balanced distribution of power. Such sharing may also aid in the reduction of ripple current when the phases are interleaved.

Current emulation may involve creating a model of the current behavior that may reflect the actual conditions within the power stage, taking into account system responses and transient phenomena. This may be used for systems where direct current measurement may be impractical or where a faster response to changes may be used.

Current emulator 233 may include advancement and propagation delay (Tprop_delay). Advancement may compensate for the propagation delay within system 100 by preemptively adjusting the PWM signal 221 to account for delays within system 100, thereby ensuring the PWM signal 221 accurately reflects the power stage adjustments. For example, advancement ensures that the timing of the PWM control signal leads system 100's physical response sufficiently to align a desired power delivery with the actual load demand.

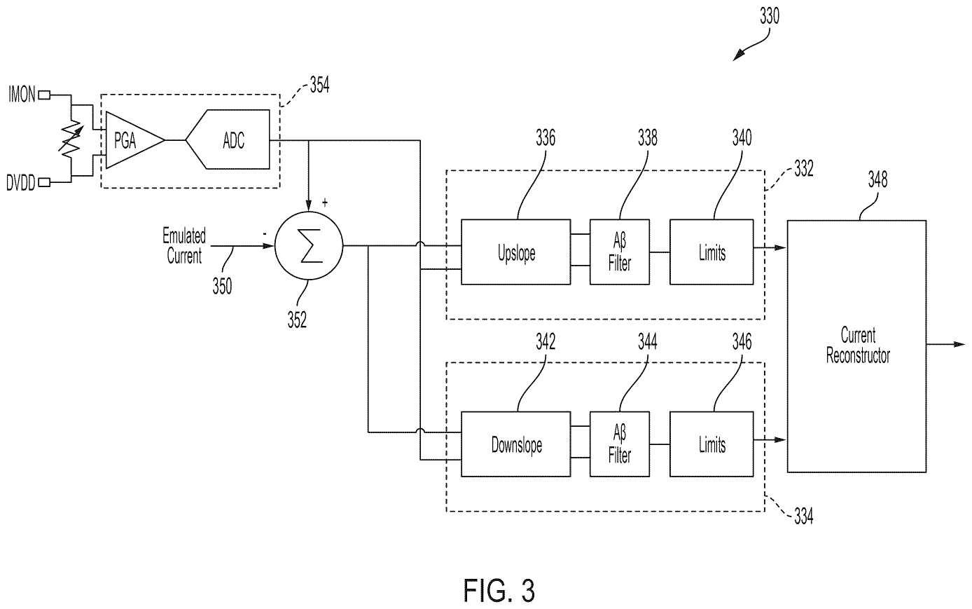

Referring now to FIG. 3 in conjunction with FIGS. 1-2, FIG. 3 depicts IMON circuitry 330. IMON circuitry 330 may include upslope channel 332, downslope channel 334, current reconstructor 348, summation 352 and PGA-ADC 354. Upslope channel 332 may include upslope 336, Aß filter 338 and limits 340. Downslope channel 334 may include downslope 342, Aß filter 346 and limits 346. Emulated current 352 may be directed to summation 352. As utilized herein, IMON reconstruction, within the context of a digital quad controller (e.g., 102), may refer to the process of recreating an accurate model or representation of the actual current flowing through each inductor phase of a power system (e.g., system 100). Such reconstruction may be particularly advantageous when direct measurement of current may be difficult, impractical, or where a more sophisticated control over the current may be used.

IMON reconstruction may utilize various signals and system parameters to extrapolate or predict the real-time current in individual phases. A method of IMON reconstruction employed by IMON circuitry 330 may include sampling the voltage across a known resistance in the power path or by using a dedicated current sensing component.

Controller 102 may utilize a combination of digital filters, such as a Kalman filter and/or an alpha-beta filter and/or alpha-beta-gamma filter, to process the sampled signals. Such filters may eliminate noise and isolate the signal component that accurately represents the current. Accordingly, IMON reconstruction may provide more accurate current information, e.g., in noisy environments or when the power system experiences rapid changes. For example, by accurately reconstructing the current, system 100 may implement protective measures before thresholds are exceeded, safeguarding against overcurrent damage.

In a system 100, current emulator block 230 block may feed back into the control algorithm, influencing the PWM signals to adjust the power delivery dynamically. The reconstructed current signal may ensure that the control loop reacts to the actual conditions within the power stage rather than just the commanded conditions, resulting in a more responsive and stable power delivery.

The controller 102 may balance output current across the switching power supplies based on the monitored current. In the context of controller 102, with multiple phases to manage, IMON reconstruction allows controller 102 to balance the load effectively, maintain phase synchronization, and prevent any one phase from being overstressed. It is particularly beneficial for systems with rapid dynamic loads, such as CPUs or graphic processing units (GPUs), where the power demand can change abruptly and frequently.

Channels 332, 334 may allow for different filter implementations for tracking the inductor upslope and downslope separately. The ability to separately track and predict the upslope and downslope rates may be advantageous because the two conditions may be individually stable and repetitive allowing for greater accuracy in tracking and predicting future events.

In some examples, αβ filters 338, 344 may include digital filters used to process the current signal. αβ filters 338, 344 may be adjustable coefficients that may provide the correction for both the current and voltage predictions. αβ may correspond to filter coefficients in a digital filter, used to determine the filter's response characteristics. Limits 340, 346 may set the maximum and minimum limits for the upslope and downslope rates. By constraining the rate at which current may change, system 100 may prevent error conditions due to an incorrect initial setting and ensure a controlled response to load changes.

Current reconstructor 348 may process outputs from channels 332, 334 and output a reconstructed inductor current and input voltage, which may be utilized for Vin sensing. Current reconstructor 348 may take the processed signal and reconstruct an accurate representation of the inductor current. This may be advantageous for system 100 to make precise adjustments based on the actual current flowing to the load. Such current reconstruction may be particularly advantageous in systems where the direct measurement of the inductor current may be impractical or where high accuracy may be used.

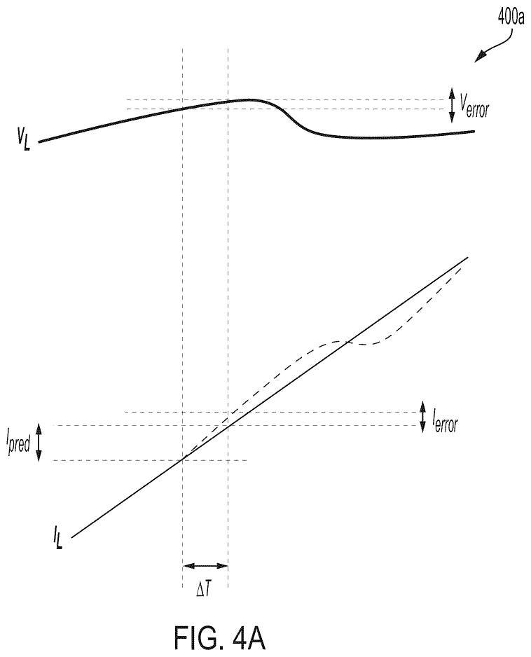

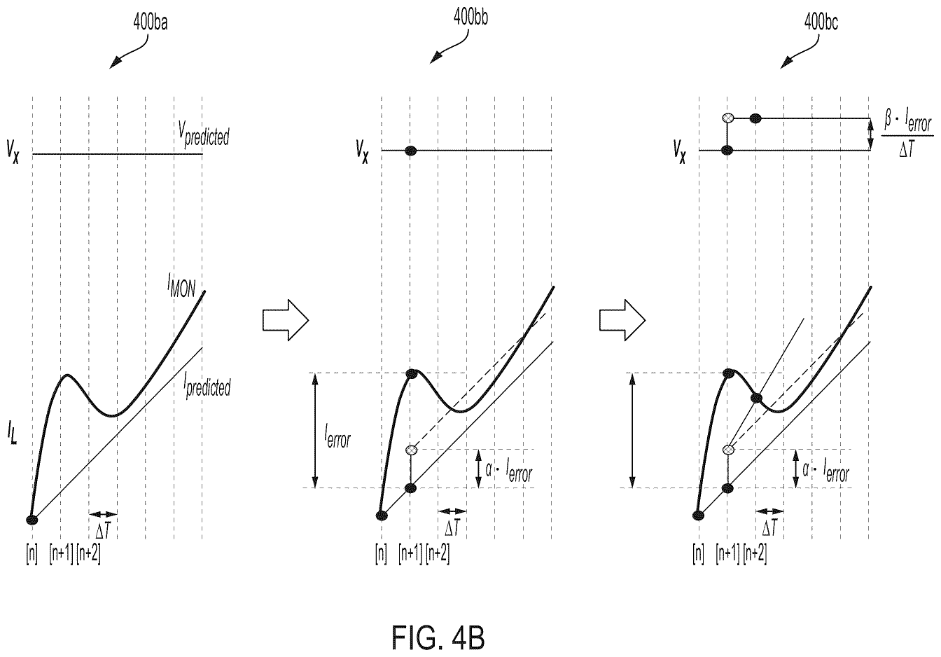

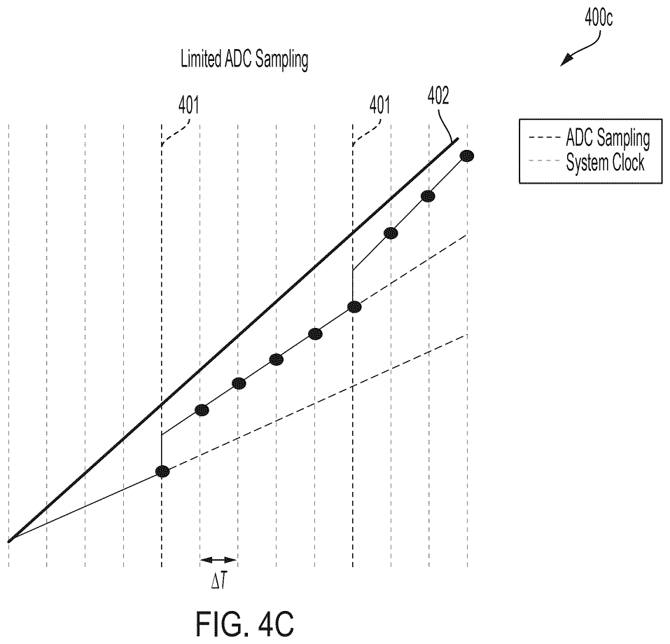

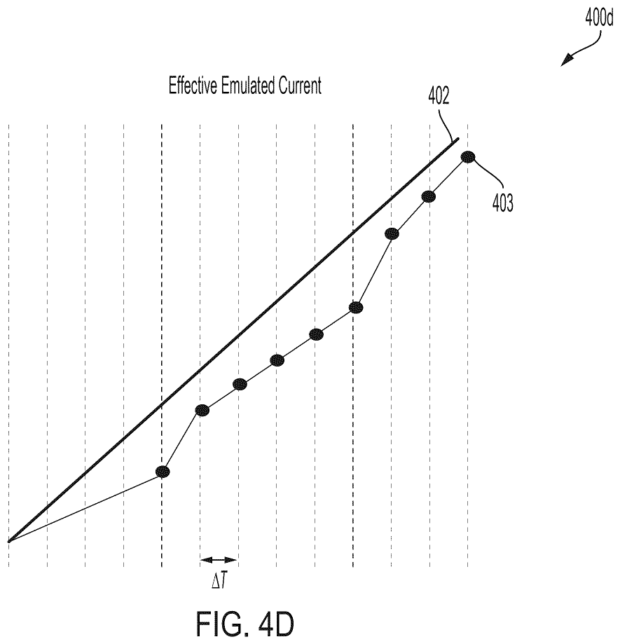

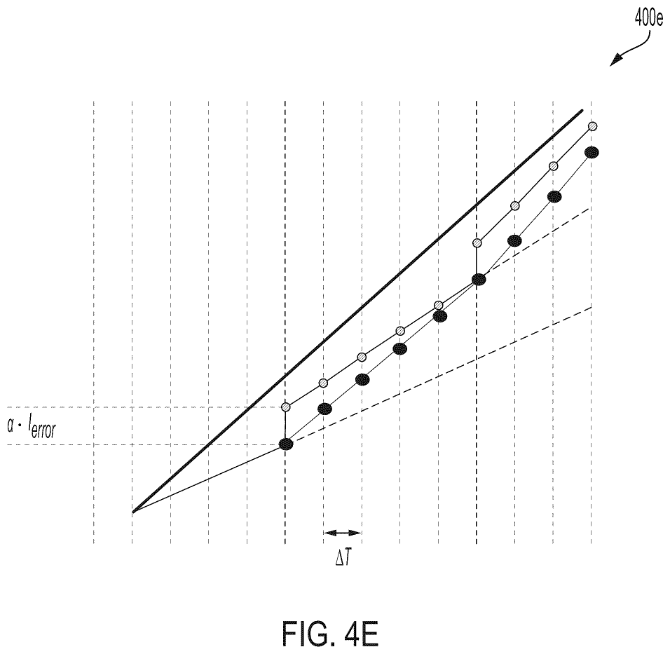

FIGS. 4A-4E correspond to a method for IMON reconstruction for extracting Vin data without sensing. FIG. 4A depicts a graph 400a showing current prediction and error measurement in system 100.

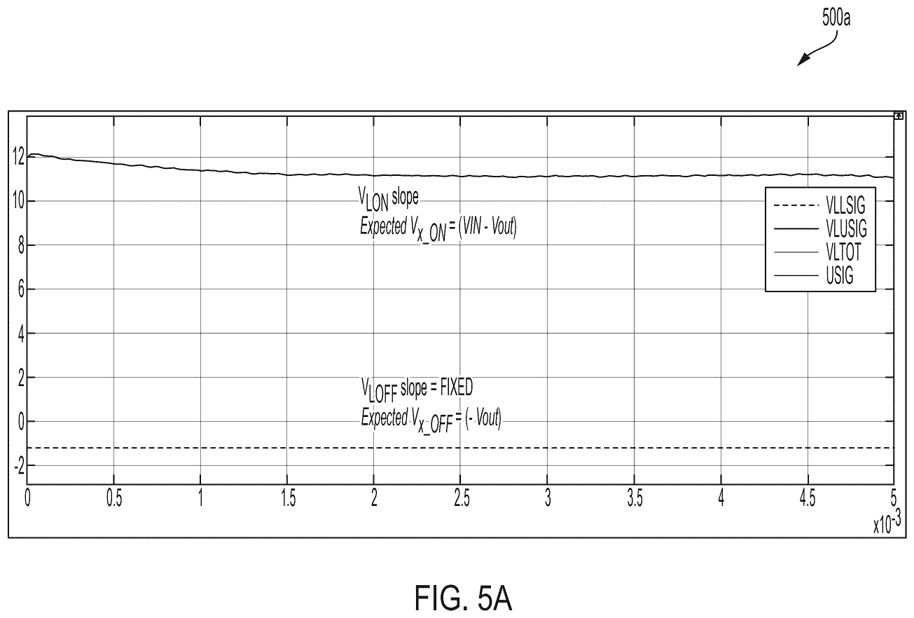

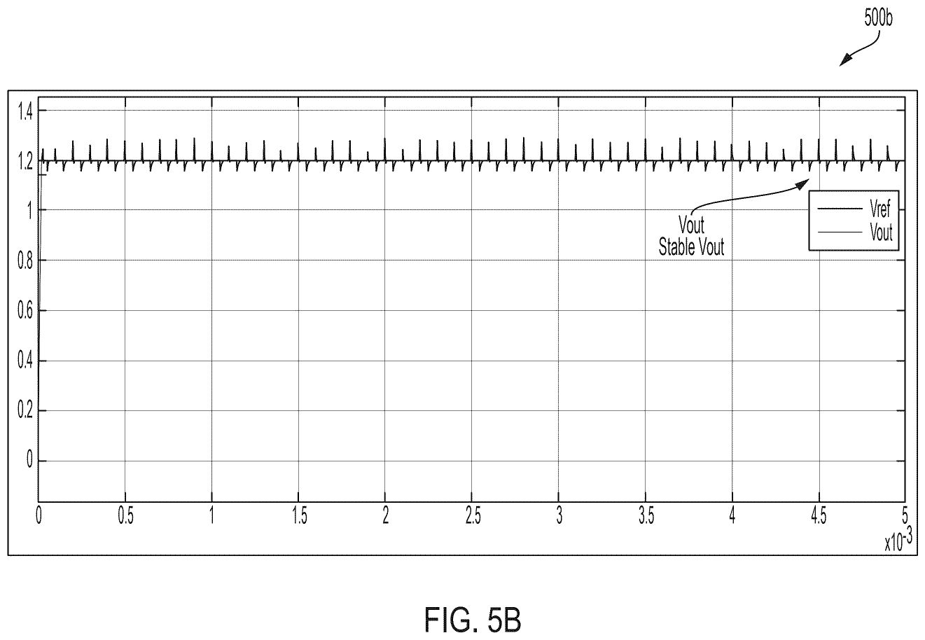

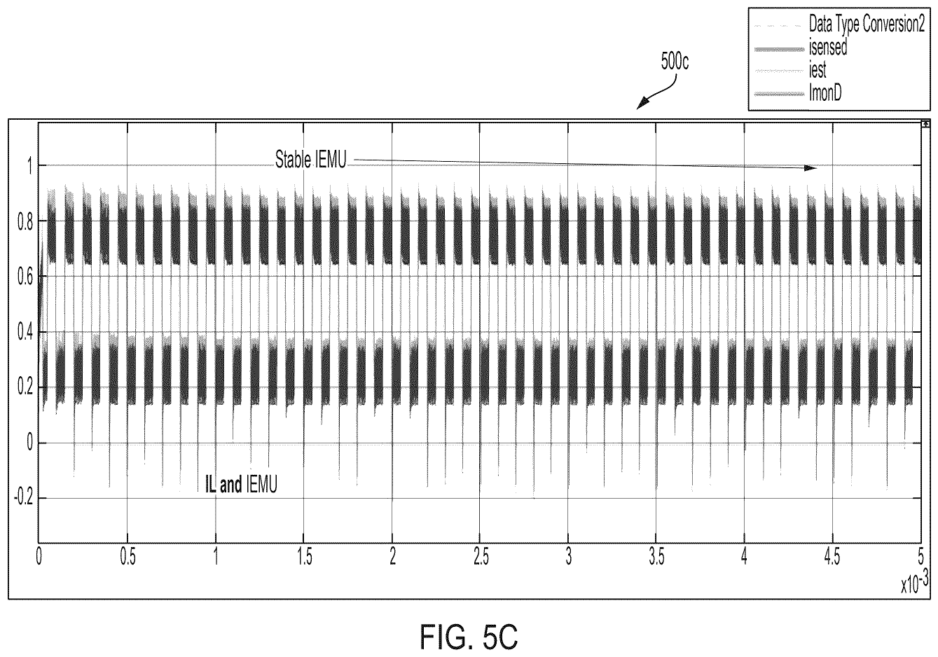

As shown in FIG. 4A, the inductor current may be emulated by using a predictive guess about the next position (Ipred) at the next sampled time interval ΔT based on an estimated inductor voltage (VL). While the predicted value may be used for the control loop as the output of the current emulator, the predicted value may also be corrected by measurement of the actual current at that point in time. The error in current is noted as Ierror which may be corrected based on the coefficient alpha while also correcting the error in the input voltage via coefficient beta. In FIG. 5A ΔT may represent the time interval over which the prediction may be made and the real current may be sampled allowing for correction. In some implementations, the prediction rate may be faster than the actual current sample rate.

Determining parameters (e.g., Ipred, Ierror, Verror, ΔT) may be advantageous in the operation of a predictive control loop 202. For example, control loop 202 may use error measurements to adjust and fine-tune output to maintain system performance and respond to changes in load or other operating conditions. Controller 102 may advantageously manage such predictions and parameter errors across multiple phases for ensuring balanced and stable operation.

As shown in FIG. 4B, graphs 400ba, 400bb, 400bc depict iterations tracking the inductor current over time while adjusting its tracking based on its estimated inductor voltage (VL). In diagram 400ba, time may be set to point [n] where the initial inductor value IMON may be known and hence Ipredicted value may be matching. Given initial settings, a predicted slope of the inductor current may be hypothesized (shown as grey line) as well as an estimated inductor voltage. In diagram 400bb time may be advanced to point [n+1] and two points may be realized—the sampled IMON and the predicted value. The difference between these may be shown as Ierror representing the error in current from actual to predicted. To predict the next point at [n+2] an error correction may be fed back into the initial starting point at [n+1] for the calculation of Ipred at [n+2]. This may be based on Ipred [N+1]+alpha*Ierror. The alpha coefficient may provide a scaling factor to account for the amount of DC correction that may occur in the predicted current. A correction in DC may be insufficient because the inductor slope may remain fixed. To address this, graph 400bc shows the final stage at time [n+1] to provide inductor current slope correction. The inductor voltage which may determine the slope of the inductor current may be corrected via Ierror and the Beta coefficient. This solution shows a Kalman filter prediction on the inductor current through an alpha/beta filter implementation.

Controller 102 may predict and correct the current using the Kalman filter and/or alpha-beta filter and/or alpha-beta-gamma filter. Such predictive filtering and error correction may be associated with a Kalman filter and/or alpha-beta filter. System 100 may implement a process of predictive filtering for error correction. Kalman filter parameters may be determined based on historical voltage data to facilitate prediction accuracy of the current (e.g., the predicted output current).

Vpredicted and Ipredicted may be the estimated future values of voltage and current, respectively. Voltage input predictions may be refined over time using historical data of an output current. Such predictions may be made based on the historical values of Vx and IL. The α error may reflect the immediate short-term prediction error for current. Stated another way, the α error may indicate the difference between the predicted current at the next time and the actual current measured. Beta (β) error may represent the rate of change of the error over time, which may be considered as a derivative of the current error, indicating whether the error is increasing or decreasing over time. Such indication may be advantageous for making accurate predictions in the next cycle. ΔT may indicate the time interval between measurements and may be used to calculate the rate of change of the current (related to β error) and to update predictions.

An alpha-beta filter may be used within a control loop to facilitate correction of monitored current prediction error. Thus, the predictive filter's role may be to minimize these errors by adjusting the predictions. Such minimization may include the α component which may adjust the prediction to correct the immediate error in the value, and the β component which may adjust for the rate of change of the error, effectively predicting the prediction error and adjusting the future value to bring the predicted curve closer to the actual curve. In the context of controller 102, such predictive correction may be advantageous for maintaining the accuracy of the current flowing through the inductor, ensuring the stability and efficiency of the power supply. The ability to anticipate and correct for both immediate errors and the trend of those errors may help maintain tight control over the output, which may be advantageous for systems with difficulty in obtaining accurate and repeatable results due to noise or limited sampling capability.

As shown in FIG. 4C, graph 400c may represent operation of an ADC sampling in relation to a system clock. Controller 102 ADCs may have a limited sampling rate. This may be shown by the dashed line 401, which may mark the points at which the ADC may take a measurement of the signal. The vertical dashed lines may represent the system clock pulses, which may provide the timing reference for the system, including the ADC. The frequency of the master clock 241 may be higher than the sampling rate of ADC to reduce the system latency and provide faster transient response.

Signal line 402 may represent the actual signal being sampled, which may indicate a linearly increasing signal over time. The black dots may be the data points where the Kalman filter may have updated its prediction of the inductor current based on the estimated slope from VL and the time period ΔT. The grey line shows the predicted current path based on an analog extrapolation. Given that the ADC may be sampled at a lower rate, shown by red lines labelled 501, the predicted inductor slope may update at that time when an actual current sample may be compared against, allowing Ierror and Verror to be calculated and adjusted.

The ADC's sampling rate may determine the resolution of the digital representation of the analog signal. If the signal changes rapidly relative to the sampling rate, there may be aliasing, where high-frequency components of the signal may be misrepresented as lower frequencies in the digital representation. Therefore, system 100 may include a higher ADC sampling rate compared to the master clock to capture the signal accurately.

Controller 102 may manage power in an electronic system by varying the e ADC sampling rate. Thus controller 102 may respond to changes in system 100. For example, when the ADC sampling rate is too low compared to the dynamics of the system, the controller may react too slowly or inaccurately, leading to potential stability or performance issues. Therefore, controller 102 may increase or decrease the ADC sampling rate during operation to ensure compliance with desired performance specifications and/or sleep modes. As shown in the graph 400d in FIG. 4D, because error may be corrected when real measurements are taken, the effective emulated current 403 may become closer to line 402 as more clock cycles transpire.

As shown in FIG. 4D, line 403 may represent the actual current as it varies over time. The other line 402 may represent the emulated or predicted current. The challenge with a slow sampled ADC is that error may build up over time and there may be a large jump in error correction at the point of sample. This may result in a disturbance in the control loop which may be non-ideal. The solution for this may be distributing the error over the cycles between the current ADC sample and the next known ADC sample point, referred to as distributed alpha error. Effective current emulation may eliminate the use for current sensing hardware, particularly in high-current or high-voltage applications. The more accurate the emulation, the more efficiently the controller may respond to changes, leading to better performance and potentially lower power consumption. For example, as shown in the graph 400e in FIG. 4E, distributed alpha error correction may be used. Such correction may improve an emulated current ramp by distributing alpha error across ADC sampling clock.

Kalman filtering may be implemented for equating positional calculation to inductor current. For clarity a brief review follows. In the domain of statistics and control theory, Kalman filtering, also known as linear quadratic estimation (LQE), may be advantageously utilized within system 100 for refining Vin predictions and adjustments over time. Kalman filtering implemented by controller 102 intelligently processes sequential measurements, which may include statistical noise and other inaccuracies, to generate more accurate state estimates than those that could be derived from any single measurement. Kalman accomplishes this by constructing a joint probability distribution over the variables for each time frame, enhancing the precision of the control system's outputs.

In controller 102 and system 100, Kalman filtering may be employed through a two-phase process including prediction and update phases. During the prediction phase, the filter may project the current state variables and their uncertainties. Subsequently, when new measurements are taken—which may include some degree of error and noise—the Kalman filter may update these predictions by taking a weighted average. The Kalman filter may assign more significance to results with a higher degree of certainty. The recursive nature of the Kalman filter may allow real-time functionality, relying on current input measurements and the previously calculated state and an uncertainty matrix. Thus, the Kalman filter may not depend on additional historical data, making it highly effective for real-time control for power management of system 100. Therefore, a Kalman filter algorithm may be based on a recursive filter to refine the predicted output by using feedback from a PWM control loop.

Such Kalman filter may include extended Kalman filtering and the unscented Kalman filter. Such filters may be based on a hidden Markov model with a continuous state space for the latent variables and Gaussian distributions for both the latent and observed variables. For example, in control loop 202 and/or controller 102, such filtering techniques may be advantageous for maintaining accurate phase balancing, Vin sensing without direct measurement, and IMON reconstruction, ultimately contributing to a highly efficient and responsive power supplies in system 100.

Kalman filtering, in context of systems 100 inductors, may operate to interpret physical system dynamics using electrical analogs. For example, while Kalman filtering for positional calculations in kinematics may be used, such positional calculation may be adapted for current estimation in inductors using the Eqn. 1-2, and 3-8. In kinematics, position x may be the integral of velocity v over time t: =∫x=∫vdt. This integral relationship may define how position changes with velocity over time. Such positional determination may be adapted instead to inductor current.

Kalman filter may use a system model and measurements over time to estimate variables in control loop 202, and/or controller 102. For inductors, controller 102 may determine the current iL through the inductor, which may be analogous to the position in a kinematic system.

Controller 102 may implement the below logic for equating such positional calculation to inductor current:

$${i}_{L} = \frac{1}{L} \int {v}_{L} dt , \qquad ( Eqn . 1 )$$

$${I}_{n} - {I}_{n - 1} = \int Vdt = Δ T ( {V}_{n} ) \qquad ( Eqn . 2 )$$

### Equation 1: Inductor Current as Position:

Eqn. 1 draws a parallel between the kinematic equation and inductor current. In this context, vL may be the voltage across the inductor, and iL may be the current through the inductor L. Integrating voltage over time may give us the change in magnetic flux, which, according to Faraday's law, may be proportional to the induced electromotive force (EMF) in the inductor. The current iL may be therefore akin to position x in the kinematic analogy. By dividing by the inductance L, controller 102 may normalize such integral to align with the inductor's current, as inductance relates the change in current to the voltage across the inductor.

### Equation 2: Current Change Over Discrete Intervals:

Eqn. 2 may indicate that the current difference between two points in time may be equal to the integral of voltage over that period, approximated as the product of a time interval ΔT and the voltage In at the latter time point. In discrete time, such equation may be a finite difference approximation, meaning that the change in current over a small time step may be roughly proportional to the voltage applied during that step.

### Implementing Kalman Filtering for Current Estimation:

In the context of the Kalman filter, these equations may serve as the system model that describes how the system behaves. Eqn. 1 and Eqn. 2 may be part of the ‘state transition’ in the Kalman filter framework, predicting the next state based on the current state. The Kalman filter may use this prediction, along with the actual measurements of voltage and current, to correct the prediction and minimize the estimation error. This may be analogous correcting positional error in a kinematic system. By updating its predictions with new measurements, the Kalman filter may refine its estimates of the current flowing through the inductor over time.

In controller 102, such implementation discussed above may be employed to accurately model and control the current in each phase of system 100 (e.g., SPS 104a, 104b, 104c, 104d), enhancing the precision of the power management process for system 100. Thus, controller 102 may operate to predict and respond to changes in load or source voltage (or load or source impedance) more effectively than non-filter aided approaches, maintaining a stable and efficient supply of power. Controller 102's Kalman filter's predictive capabilities may be advantageous in system 100 where system 100 inductors may be part of a dynamic power supply, having rapid response and adaptation to changing electrical conditions.

Thus, similar to the area under the velocity-time curve yielding position in a kinematic framework, where x=∫ v dt, in some examples, the integral of voltage over time in an electrical context may be implemented to deduce the corresponding current through an inductor in controller 102. Accordingly, such approach may be employed to correlate positional calculations with inductor current for predicting Vin, without Vin sensing hardware. For example, such correlation may equate to the voltage across the inductor, which during the ON time may be used as a substantial or close approximation of Vin. Thus, because the output voltage is known, input voltage may be derived.

Equations 1-2 may be utilized by controller 102 for determining Vin:

$${\hat{I}}_{n} ← {\hat{I}}_{n - 1} + Δ T {\hat{V}}_{n - 1} \qquad ( Eqn . 3 )$$

$${\hat{V}}_{n} ← {\hat{V}}_{n - 1} \qquad ( Eqn . 4 )$$

$${\hat{r}}_{n} ← {I}_{n} - {\hat{I}}_{n} \qquad ( Eqn . 5 )$$

$${\hat{I}}_{n} ← {\hat{I}}_{n} + α {\hat{r}}_{n} \qquad ( Eqn . 6 )$$

$${\hat{V}}_{n} ← {\hat{V}}_{n} + \frac{β {\hat{r}}_{n}}{Δ T} \qquad ( Eqn . 7 )$$

$$where : 0 < α < 1 ; and 0 < β \leq 2$$

Accordingly, based on Eqns. 1-2 above, a method of iterative loop of prediction may be provided as shown by FIGS. 4A-4E and Eqns. 3-7 above.

FIGS. 5A-5C depict 500a, 500b, 500c showing simulation outputs displaying robust signal characteristics. As shown in FIG. 5A, so-called V_ON Slope, may display the expected voltage during the ‘on’ phase of a switching cycle. The ‘V_ON slope’ graph may show a stable line labeled as “Expected V_x_on=(VIN−Vout)”, indicating that the expected voltage may be calculated from the input voltage (VIN) minus the output voltage (Vout), which may represent a predictive estimate of the voltage across an inductor when the switch is closed in a buck converter topology.

As shown in FIG. 5B, a simulation may be seen that highlights two waveforms Vout—the actual output voltage of the power supply and the reference voltage which may be the target voltage. During the simulation constant load steps may be applied and removed to the output causing a fast transient event. The spikes shown in Vout may be a result of the load transient and clearly show a stable and controlled response with the output quickly returning back to the desired target voltage. Graph 500b may be substantially flat, indicating that the output voltage may be stable over time, which may be a desirable characteristic for power supply systems (e.g., system 100). Such output may be advantageous in the context of controller 102 for ensuring that phases, or SPS 104 may provide a stable output.

As shown in FIG. 5C, graph 500c may be the same conditions as shown in FIG. 5B except that the current waveforms are shown responding to the load transients. FIG. 5B may show both the actual inductor current waveform (IL) and the emulated inductor current waveform from the output of the Kalman filter (IEMU). Graph 500c may show the effectiveness of the current emulation in tracking the actual inductor current.

The ‘IL and IEMU’ signal may be indicative of the current monitoring and emulation capability of controller 102. Such emulation capability may be part of the feedback control system of controller 102 (e.g., control loop 202), where controller may match the emulated current (IEMU) to the actual inductor current (IL) as closely as possible to maintain precision in power delivery.

As shown by 500a-500c, such stable signal characteristics signify that system 100 and controller 102 may maintain robust operation handling the dynamic aspects of voltage and current regulation effectively. Accordingly system 100 may provide clean and stable power, advantageous for sensitive electronic applications.

Accordingly the examples herein may provide a sophisticated system (e.g., system 100) to manage and regulate a multiphase switching power supply (e.g., 104) with high precision and adaptability. The integration of advanced control algorithms, including the Kalman filtering technique, may enable system 100 to process noisy and imprecise data to produce highly accurate estimations of both the inductor current (IMON) and the input voltage (Vin), despite the absence of direct measurement. Advantageously system 100's architecture, may facilitate a dual predictive-corrective cycle, used for dynamic control applications. The predictive aspect, grounded in Kalman filtering, may estimate the power stages' behavior, while the corrective phase may utilize feedback to minimize errors, ensuring that the power output closely tracks the intended performance criteria.

System 100 robust signal characteristics may underscore stability and reliability. Whether examining the voltage across phases during the PWM ‘on’ or “off” state or scrutinizing the output voltage and current emulation for stability, system 100 may exhibit a steadiness that may be advantageous for sensitive electronic applications that rely on a clean and stable power supply.

Controller 102's adaptability may be further evidenced by its use of feedback signals to dynamically adjust PWM signals, optimizing power delivery and ensuring efficient system operation. Controller 102 may encompass a design approach that simplifies the hardware for power management. By reducing dependence on multiple sensors and harnessing the power of predictive algorithms, controller 102 may provide a cost-effective solution while advancing the state of the art in power management technology. Such comprehensive approach, with a focus on predictive accuracy, real-time adaptability, and system-wide stability, may provide a leap forward in the field of power electronics.

The examples described herein may be embodied in systems, apparatus, methods, computer programs and/or articles depending on the desired configuration. Any methods or the logic flows depicted in the accompanying figures and/or described herein do not necessarily require the particular order shown, or sequential order, to achieve desirable results. The implementations set forth in the foregoing description do not represent all implementations consistent with the subject matter described herein. Instead, they are merely some examples consistent with aspects related to the described subject matter. Although a few variations have been described in detail above, other modifications or additions are possible. In particular, further features and/or variations can be provided in addition to those set forth herein. The implementations described above can be directed to various combinations and subcombinations of the disclosed features and/or combinations and subcombinations of further features noted above. Furthermore, above described advantages are not intended to limit the application of any issued claims to processes and structures accomplishing any or all of the advantages.

Furthermore, any reference to this disclosure in general or use of the word “embodiment” in the singular is not intended to imply any limitation on the scope of the claims set forth below. Multiple embodiments may be set forth according to the limitations of the multiple claims issuing from this disclosure, and such claims accordingly define the embodiment(s) herein, and their equivalents, that are protected thereby.

In the claims, any reference signs placed between parentheses shall not be construed as limiting the claim. The word “comprising” or “including” does not exclude the presence of elements or steps other than those listed in a claim. In a device claim enumerating several means, several of these means may be embodied by one and the same item of hardware. The word “a” or “an” preceding an element does not exclude the presence of a plurality of such elements. In any device claim enumerating several means, several of these means may be embodied by one and the same item of hardware. The mere fact that certain elements are recited in mutually different dependent claims does not indicate that these elements cannot be used in combination.

Although the description provided above provides detail for the purpose of illustration based on what is currently considered to be the most practical and preferred examples, it is to be understood that such detail is solely for that purpose and that the disclosure is not limited to the expressly disclosed examples, but, on the contrary, is intended to cover modifications and equivalent arrangements that are within the spirit and scope of the appended claims. For example, it is to be understood that the present disclosure contemplates that, to the extent possible, one or more features of any example can be combined with one or more features of any other example.

1. A system for switching power supply, comprising:
a controller;
a plurality of switching power supplies; and
a processing device operable to:
determine a monitored current of at least one switching power supply of the plurality of switching power supplies;
determine, based on the monitored current, an induction prediction;
determine, a voltage input prediction corresponding to the at least one switching power supply based on the induction prediction; and
output the voltage input prediction to the at least one switching power supply.

2. The system of claim 1, wherein the monitored current is determined by emulating an actual current using a Kalman filter.

3. The system of claim 1, wherein the controller uses a control loop that uses predicted output current to dynamically adjust pulse-width modulation (PWM) signals for the plurality of switching power supplies.

4. The system of claim 1, wherein determining the voltage input prediction includes refining the voltage input prediction over time using historical data of an output current.

5. The system of claim 1, wherein the controller is further operable to balance output current across the plurality of switching power supplies based on the monitored current.

6. The system of claim 1, wherein the controller is operable to use an alpha-beta filter within a control loop to facilitate correction of monitored current prediction error.

7. The system of claim 1, wherein the controller is operable to trigger a fault condition when an over-temperature event is detected.

8. The system of claim 1, wherein the processing device is further operable to:
determine, based on a predicted output current, a set of pulse-width modulation (PWM) signals; and
send the set of PWM signals to regulate the at least one switching power supply of the plurality of switching power supplies.

9. The system of claim 8, wherein the processing device is further operable to:
determine a plurality of Kalman filter parameters based on historical voltage data to facilitate prediction accuracy of the predicted output current.

10. The system of claim 8, wherein the processing device is further operable to:
determine the voltage input prediction based on the predicted output current without direct voltage input sensing.

11. The system of claim 8, wherein the set of PWM signals are adjusted in response to the predicted output current to facilitate power delivery across the plurality of switching power supplies.

12. The system of claim 8, wherein the processing device is further operable to:
use a Kalman filter algorithm based on a recursive filter to refine the predicted output current by using feedback from a PWM control loop.

13. The system of claim 12, wherein the processing device is further operable to:
update the voltage input prediction based on variations in one or more of load or source impedance.

14. A system for controlling a multiphase switching power supply, the system comprising:
a control loop operable to manage a plurality of switching power supplies; and
a hysteresis window generator operable to dynamically adjust switching thresholds for the plurality of switching power supplies.

15. The system of claim 14, further comprising a voltage regulator, wherein the voltage regulator comprises one or more of a programmable gain amplifier (PGA), an analog-to-digital converter (ADC), or a proportional integral derivative (PID) controller.

16. The system of claim 14, further comprising a frequency locked loop operable to receive a pulse width modulation (PWM) output and provide a correction signal to the hysteresis window generator.

17. The system of claim 14, further comprising a current emulator operable to provide an emulated current signal to pulse width modulation (PWM) circuitry.

18. The system of claim 14, further comprising a filter.

19. A method, comprising:
determining a monitored current of at least one switching power supply of a plurality of switching power supplies;
determining, based on the monitored current, an induction prediction;
determining, a voltage input prediction corresponding to the at least one switching power supply based on the induction prediction; and
outputting the voltage input prediction to the at least one switching power supply.

20. The method of claim 19, further comprising:
determining the monitored current by emulating an actual current using a Kalman filter.
